(19) United States
(12) Patent Application Publication
(10) Pub. No.: US 2024/0372275 A1
(43) Pub. Date: Nov. 7, 2024

(54) Electric Connection Member and Electric Connection Assembly

(71) Applicants: Tyco Electronics (Suzhou) Ltd., Suzhou City (CN); Tyco Electronics Technology (SIP) Ltd., Suzhou (CN); Tyco Electronics (Shanghai) Co., Ltd., Shanghai (CN)

(72) Inventors: Jinshun (Jet) Wang, Suzhou (CN); Fangyue Jason Zhu, Shanghai (CN); Ming Xu, Shanghai (CN); Jianwei Qi, Suzhou (CN)

(73) Assignees: Tyco Electronics (Suzhou) Ltd., Suzhou City (CN); Tyco Electronics Technology (SIP) Ltd., Suzhou (CN); Tyco Electronics (Shanghai) Co., Ltd., Shanghai (CN)

(21) Appl. No.: 18/653,491

(22) Filed: May 2, 2024

(30) Foreign Application Priority Data
May 4, 2023 (CN) 202310489188.X

(51) Int. Cl. H01R 4/34; H02J 7/00

(52) U.S. Cl. CPC H01R 4/34; H02J 7/0045; H02J 7/00309

(57) ABSTRACT

An electric connection member includes an electric transmission body having a shape of a hollow tube, a first connection end connected to a first end of the electric transmission body, and a second connection end connected to a second end of the electric transmission body. The electric connection member is an integral piece. An inner cavity of the electric transmission body serves as a flow channel for a cooling fluid. A first fluid through-hole and a second fluid through-hole are formed in a pair of circumferential walls at the first end and the second end of the electric transmission body. The cooling fluid flows into the electric transmission body through one of the first fluid through-hole and the second fluid through-hole and flow out of the electric transmission body through the other.

### CROSS-REFERENCE TO RELATED APPLICATION

This application claims the benefit of the filing date under 35 U.S.C. § 119 (a)-(d) of Chinese Patent Application No. 202310489188.X, filed on May 4, 2023.

### FIELD OF THE INVENTION

The present invention relates to an electric connection member and an electric connection assembly comprising the electric connection member, in particular to an electric connection member for detachable electrical connection with a charging seat.

### BACKGROUND

In order to achieve electric connection between a charging gun and a battery pack, it is usually necessary to provide a charging seat, a cable, and a connector. The charging seat includes a charging seat housing and a charging terminal arranged in the charging seat housing. The connector includes a connector housing and a connection terminal arranged in the connector housing. One end of the cable is electrically connected to the charging terminal of the charging seat. The other end of the cable is electrically connected to the connection terminal of the connector.

Therefore, it is necessary to provide a separate charging terminal for the charging seat and separate connection terminal for the connector, which will result in higher costs. It is also necessary to crimp or weld the end of the cable to the charging terminal of the charging seat or the connection terminal of the connector, which will reduce manufacturing efficiency. In addition, there is a significant resistance in the connection between the cable and the charging terminal, or between the cable or the connection terminal, which can cause a significant temperature rise in the product and seriously affect the safety of the charging equipment.

In order to improve charging speed, the cable needs to carry large current, which can lead to a higher temperature rise. To reduce temperature rise, large cross-sectional cable is usually used, which can lead to increased cost and volume.

### SUMMARY

An electric connection member includes an electric transmission body having a shape of a hollow tube, a first connection end connected to a first end of the electric transmission body, and a second connection end connected to a second end of the electric transmission body. The electric connection member is an integral piece. An inner cavity of the electric transmission body serves as a flow channel for a cooling fluid. A first fluid through-hole and a second fluid through-hole are formed in a pair of circumferential walls at the first end and the second end of the electric transmission body. The cooling fluid flows into the electric transmission body through one of the first fluid through-hole and the second fluid through-hole and flow out of the electric transmission body through the other.

### BRIEF DESCRIPTION OF THE DRAWINGS

Features of the present invention will become more apparent by describing in detail exemplary embodiments thereof with reference to the accompanying drawings, in which:

FIG. 1 shows an illustrative perspective view of an electric connection assembly according to an exemplary embodiment of the present invention;

FIG. 2 shows a cross-sectional view of an electric connection assembly according to an exemplary embodiment of the present invention;

FIG. 3 shows an illustrative perspective view of an electric connection assembly according to an exemplary embodiment of the present invention, where the charging seat housing and connector housing are not shown;

FIG. 4 shows a vertical sectional view of an electric connection assembly according to an exemplary embodiment of the present invention, where the charging seat housing and connector housing are not shown;

FIG. 5 shows a horizontal sectional view of an electric connection assembly according to an exemplary embodiment of the present invention, where the charging seat housing and connector housing are not shown;

FIG. 6 shows an illustrative perspective view of the first pipe connection member and the second pipe connection member according to an exemplary embodiment of the present invention; and

FIG. 7 shows a cross-sectional view of the first and second pipe connection members according to an exemplary embodiment of the present invention.

### DETAILED DESCRIPTION OF EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

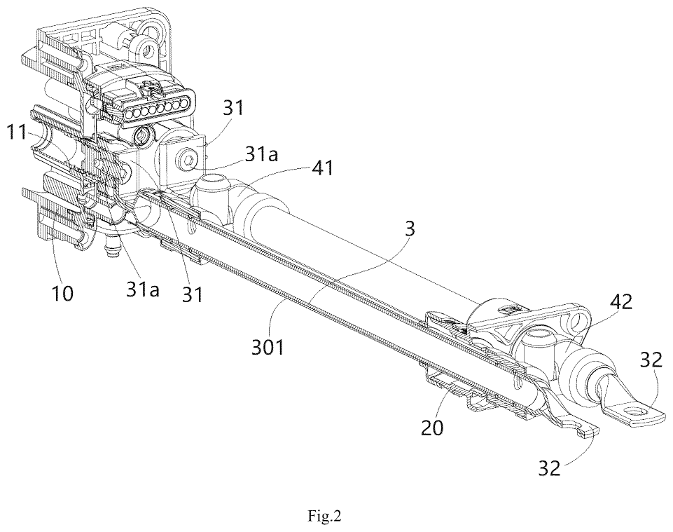

As shown in FIGS. 2 to 5, in an exemplary embodiment of the present invention, an electric connection member 3 is disclosed. The electric connection member 3 includes an electric transmission body 30 and a first connection end 31. The electric transmission body 30 is in a hollow tube shape. The first connection end 31 is connected to one end of the electric transmission body 30. In the illustrated embodiment, the electric connection member 3 is an integral piece, and the first connection end 31 is suitable for detachable electric connection to the charging terminal 11 of the charging seat 1.

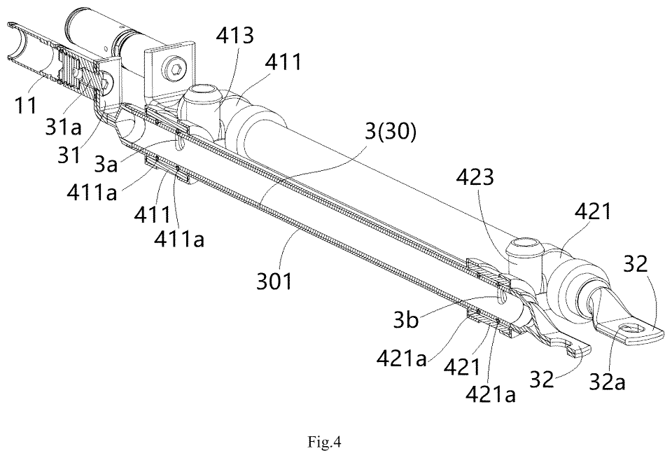

In the illustrated embodiments, the inner cavity of the electric transmission body 30 serves as a cooling fluid flow channel, and a first fluid through-hole 3a and a second fluid through-hole 3b are formed in the circumferential walls at both ends of the electric transmission body 30, as shown in FIG. 4, to allow the cooling fluid to flow into the electric transmission body 30 through one of the first fluid through-hole 3a and the second fluid through-hole 3b, and flow out of the electric transmission body 30 through the other of the first fluid through-hole 3a and the second fluid through-hole 3b.

In the illustrated embodiments, the electric transmission body 30 of the electric connection member 3 is used for transmitting both current and cooling fluid, thus reducing the temperature rise of the electric connection member 3. In addition, in the present invention, the first connection end 31 of the electric connection member 3 can be detachably connected to the charging terminal 11 of the charging seat 1.

As shown in FIG. 4, in the illustrated embodiments, the electric connection member 3 further includes a second connection end 32. The second connection end 32 is connected to the other end of the electric transmission body 30 and serves as a connecting terminal of a connector 2. In the illustrated embodiment, the second connection end 32 is adapted to be detachably electrically connected to a busbar of a battery pack.

In the illustrated embodiments, the electric connection member 3 is made of a single tubular piece, one end of which is flattened and bent to form the first connection end 31, and the other end of the tubular piece is flattened to form the second connection end 32. The middle part of the tubular piece is served as the electric transmission body 30, shown in FIG. 4, and the two ends of the electric transmission body 30 are respectively sealed by the flattened first connection end 31 and the flattened second connection end 32.

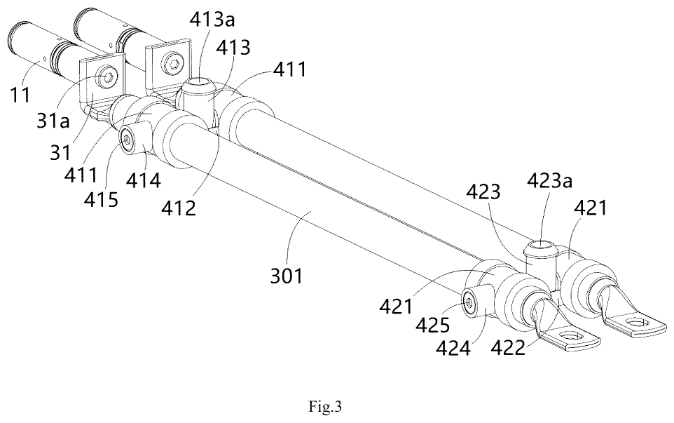

As shown in FIGS. 3 and 4, in the illustrated embodiments, a first connection hole is formed in the first connection end 31 that allows a first threaded connection member 31a to pass through, so that the first connection end 31 can be connected to the charging terminal 11 through the first threaded connection member 3la. A second connection hole 32a is formed in the second connection end 32 to allow a second threaded connection member to pass through, so that the second connection end 32 can be connected to the busbar through the second threaded connection member.

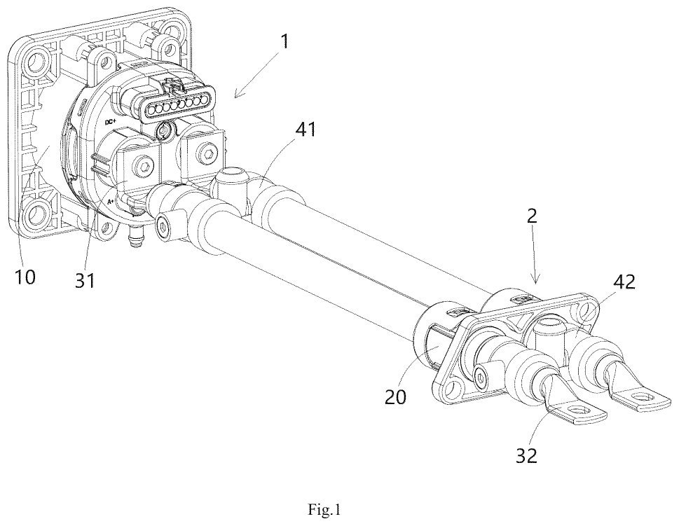

In another exemplary embodiment of the present invention, an electric connection assembly is also disclosed. The electric connection assembly, as shown in FIGS. 1 and 2, includes two aforementioned electric connection members 3, an insulation first pipe connection member 41, and an insulation second pipe connection member 42. The insulation first pipe connection member 41 is fitted on a first end of each of two electric transmission bodies 30 to connect the first fluid through-holes 3a at one ends of the two electric transmission bodies 30 and connect the first fluid through-holes 3a to a cooling fluid circuit. The insulation second pipe connection member 42 is fitted on a second end of each of the electric transmission bodies 30 to connect the second fluid through-holes 3b at the second ends of two electric transmission bodies 30 and connect the second fluid through-holes 3b to the cooling fluid circuit.

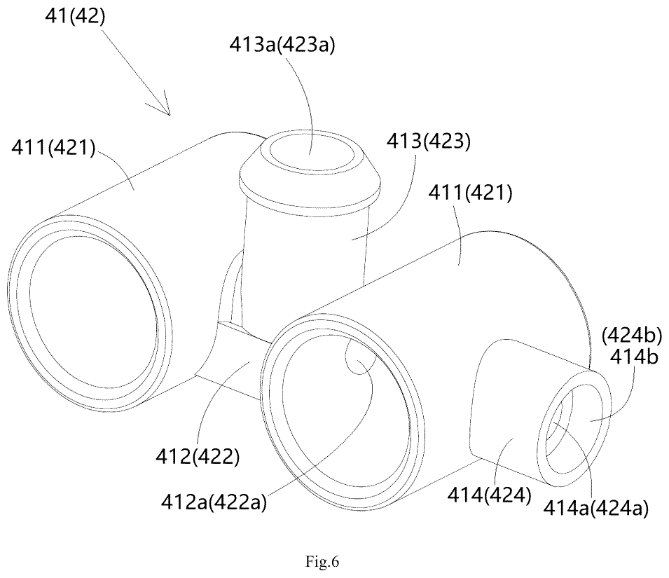

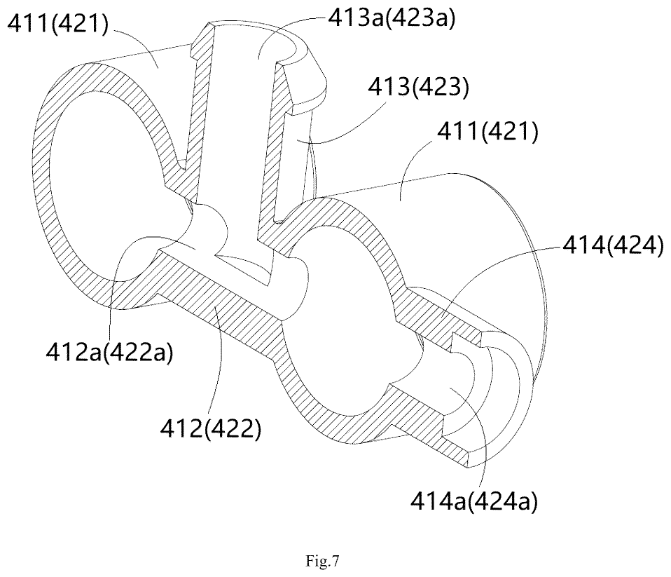

As shown in FIGS. 6 and 7, in the illustrated embodiment, the first pipe connection member 41 includes two first tubular parts 411, a first communication part 412, and a first pipe joint 413. Two first tubular parts 411 are respectively fitted on first ends of two electric transmission bodies 30. The first communication part 412 is connected between two first tubular parts 411 and has a first communication hole 412a. The first pipe joint 413 is connected to the first communication part 412 and has a first connection hole 413a. The first connection hole 413a is connected to the first communication hole 412a, the first communication hole 412a is connected to the first fluid through-holes 3a of two electric transmission bodies 30, and the first pipe joint 413 is used to connect to the cooling fluid circuit.

As shown in FIGS. 6 and 7, in the illustrated embodiment, the second pipe connection member 42 includes two second tubular parts 421, a second communication part 422, and a second pipe joint 423. Two second tubular parts 421 are respectively fitted on the other ends of two electric transmission bodies 30. The second communication part 422 is connected between two second tubular parts 421 and has a second communication hole 422a. The second pipe joint 423 is connected to the second communication part 422 and has a second connection hole 423a. The second connection hole 423a is connected to the second communication hole 422a, the second communication hole 422a is connected to the second fluid through-holes 3b of two electric transmission bodies 30, and the second pipe joint 423 is used to connect to the cooling fluid circuit.

In an exemplary embodiment of the present invention, the first pipe connection member 41 and the second pipe connection member 42 can be completely identical and interchangeable, thereby reducing manufacturing costs and case of use.

As shown in FIG. 4, in the illustrated embodiment, two first sealing rings 411a are sleeved on one end of the electric transmission body 30. Two first sealing rings 411a are respectively positioned on the inner sides of both ends of the first tubular part 411 and compressed between the first tubular part 411 and the electric transmission body 30 to achieve sealing between the two.

As shown in FIG. 4, in the illustrated embodiments, two second sealing rings 421a are sleeved on the second end of the electric transmission body 30. The two second sealing rings 421a are respectively positioned on the inner sides of the two ends of the second tubular part 421 and compressed between the second tubular part 421 and the electric transmission body 30 to achieve sealing between the two.

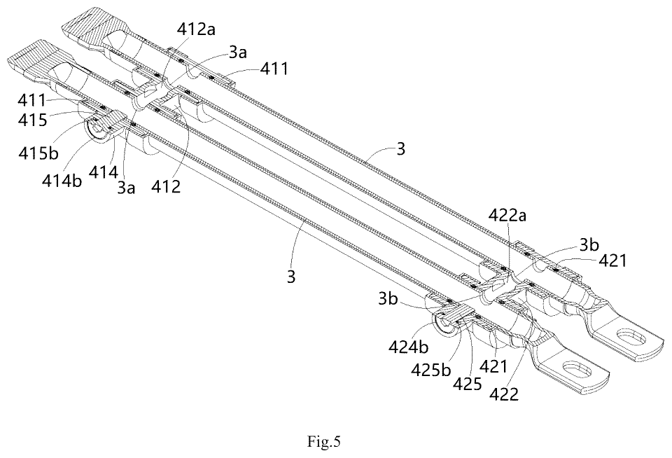

As shown in FIGS. 3 and 5, in the illustrated embodiments, a raised first mounting portion 414 is formed on the outer surface of the first tubular part 411, a first threaded hole 414a is formed in the first mounting portion 414, and a first positioning hole corresponding to the first threaded hole 414a is formed on one end of the electric transmission body 30. The electric connection assembly further includes a first positioning screw 415, which is threaded into the first threaded hole 414a and inserted into the first positioning hole to prevent axial movement and circumferential rotation of the first pipe connection member 41 relative to the electric transmission body 30.

As shown in FIGS. 5 and 7, in the illustrated embodiments, a raised second mounting portion 424 is formed on the outer surface of the second tubular part 421, a second threaded hole 424a is formed in the second mounting portion 424, and a second positioning hole corresponding to the second threaded hole 424a is formed on one end of the electric transmission body 30. The electric connection assembly also includes a second positioning screw 425, which is threaded into the second threaded hole 424a and inserted into the second positioning hole to prevent axial movement and circumferential rotation of the second pipe connection member 42 relative to the electric transmission body 30.

As shown in FIGS. 5 and 6, in the illustrated embodiments, a first recess 414b is formed on the first mounting portion 414 to accommodate the head of the first positioning screw 415, and a first sealing ring 415b is provided in the first recess 414b. The first sealing ring 415b is compressed between the head of the first positioning screw 415 and the bottom surface of the first recess 414b to achieve sealing between the two.

As shown in FIGS. 5 and 6, in the illustrated embodiments, a second recess 424b is formed on the second mounting portion 424 to accommodate the head of the second positioning screw 425, and a second sealing ring 425b is provided in the second recess 424b. The second sealing ring 425b is compressed between the head of the second positioning screw 425 and the bottom surface of the second recess 424b to achieve sealing between the two.

As shown in FIGS. 2 to 4, in the illustrated embodiments, the electric connection assembly further comprises a heat shrink tube 301, which is heat shrunk on the outer side of the electric transmission body 30 of the electric connection member 3 to form an external insulation layer of the electric transmission body 30. The two ends of the first tubular part 411 and the two ends of the second tubular part 421 are wrapped in the heat shrink tube 301.

As shown in FIGS. 1 and 2, in the illustrated embodiments, the electric connection assembly further comprises a charging seat 1, which comprises a charging seat housing 10 and a charging terminal 11 installed in the charging seat housing 10. The first connection end 31 of the electric connection member 3 is detachably connected to the charging terminal 11. In the illustrated embodiments, the electric connection assembly further comprises a first threaded connection member 31a, which passes through the first connection end 31 of the electric connection member 3 and is threaded to the charging terminal 11 to secure the first connection end 31 to the charging terminal 11.

As shown in FIGS. 1 and 2, in the illustrated embodiments, the electric connection assembly further comprises a connector 2, which includes a connector housing 20. The second connection end 32 of the electric connection member 3 is inserted into the connector housing 20 to form a connection terminal of the connector 2 for electric connection with the busbar of the battery pack.

As shown in FIGS. 1 and 2, in the illustrated embodiments, the second pipe connection member 42 is located inside the connector housing 20 for connection with the cooling fluid circuit located inside the battery pack. However, the present invention is not limited to the illustrated embodiments, for example, the second pipe connection member 42 may be located outside the connector housing 20 for connection with a cooling fluid circuit located outside the battery pack.

As shown in FIG. 2, in the illustrated embodiment, the first connection end 31 of the electric connection member 3 is detachably connected to the charging terminal 11 of the charging seat 1. The second connection end 32 of the electric connection member 3 serves as the connection terminal of connector 2 and is adapted to be detachably electrically connected to the busbar of the battery pack.

The present invention is not limited to the illustrated embodiments. For example, in another exemplary embodiment of the present invention, the first connection end 31 of the electric connection member 3 can be inserted into the charging seat housing 10 to serve as the charging terminal of the charging seat 1. The second connection end 32 of the electric connection member 3 is adapted to be detachably electrically connected to the connection terminal of connector 2. At this time, the first connection end 31 of the electric connection member 3 is suitable for mating with the mating terminal of the charging gun. For example, in another exemplary embodiment of the present invention, the first connection end 31 of the electric connection member 3 is suitable for detachable electric connection to the charging terminal 11 of the charging seat 1. The second connection end 32 of the electric connection member 3 is adapted to be detachably electrically connected to the connection terminal of connector 2.

In the embodiments shown in FIGS. 1 to 7, the electric connection member 3 is used for the electric connection between the charging seat 1 and connector 2. However, the present invention is not limited to the illustrated embodiments, for example, in another exemplary embodiment of the present invention, an electric connection member 3 is also disclosed. The electric connection member includes an electric transmission body 30, a first connection end 31 and a second connection end 32. The electric transmission body 30 is in the shape of a hollow tube. The first connection end 31 is connected to one end of the electric transmission body 30. The second connection end 32 is connected to the other end of the electric transmission body 30. The electric connection member 3 is an integral piece, and the first connection end 31 is suitable for detachable electric connection to a connection terminal of one connector or the second connection end 32 is suitable for detachable electric connection to a connection terminal of another connector 2. The inner cavity of the electric transmission body 30 is served as a cooling fluid flow channel, and a first fluid through-hole 3a and a second fluid through-hole 3b are formed in the circumferential walls at both ends of the electric transmission body 30, respectively, to allow the cooling fluid to flow into the electric transmission body 30 through one of the first fluid through-hole 3a and the second fluid through-hole 3b, and flow out of the electric transmission body 30 through the other of the first fluid through-hole 3a and the second fluid through-hole 3b.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. An electric connection member, comprising:
an electric transmission body having a shape of a hollow tube;
a first connection end connected to a first end of the electric transmission body; and
a second connection end connected to a second end of the electric transmission body, the electric connection member is an integral piece, the first connection end is detachably electrically connected to a charging terminal of a charging seat or the second connection end is detachably electrically connected to a connection terminal of a connector, an inner cavity of the electric transmission body serves as a flow channel for a cooling fluid, a first fluid through-hole and a second fluid through-hole are formed in a pair of circumferential walls at the first end and the second end of the electric transmission body, the cooling fluid flows into the electric transmission body through one of the first fluid through-hole and the second fluid through-hole and flow out of the electric transmission body through the other of the first fluid through-hole and the second fluid through-hole.

2. The electric connection member of claim 1, wherein the first connection end is detachably electrically connected to the charging terminal of the charging seat and the second connection end serves as the connection terminal of the connector and is detachably electrically connected to a busbar of a battery pack.

3. The electric connection member of claim 1, wherein the first connection end serves as the charging terminal of the charging seat, the first connection end is matable with a mating terminal of a charging gun, the second connection end is detachably electrically connected to the connection terminal of the connector.

4. The electric connection member of claim 1, wherein the first connection end is detachably electrically connected to the charging terminal of the charging seat, the second connection end is detachably electrically connected to the connection terminal of the connector.

5. The electric connection member of claim 2, wherein the electric connection member is made of a single tubular piece, an end of the single tubular piece is flattened and bent to form the first connection end and another end of the single tubular piece is flattened to form the second connection end, a middle part of the single tubular piece serves as the electric transmission body, the first end and the second end of the electric transmission body are respectively sealed by the first connection end and the second connection end.

6. The electric connection member of claim 2, wherein:
a first connection hole is formed in the first connection end that receives a first threaded connection member to connect the first connection end to the charging terminal; and/or
a second connection hole is formed in the second connection end that receives a second threaded connection member to connect the second connection end to the busbar.

7. An electric connection assembly, comprising:
a pair of electric connection members, each of the electric connection members including:
an electric transmission body having a shape of a hollow tube;
a first connection end connected to a first end of the electric transmission body; and
a second connection end connected to a second end of the electric transmission body, the electric connection member is an integral piece, an inner cavity of the electric transmission body serves as a flow channel for a cooling fluid, a first fluid through-hole and a second fluid through-hole are formed in a pair of circumferential walls at the first end and the second end of the electric transmission body, the cooling fluid flows into the electric transmission body through one of the first fluid through-hole and the second fluid through-hole and flow out of the electric transmission body through the other of the first fluid through-hole and the second fluid through-hole;
a first pipe connection member that is insulative and fitted on the first end of each of the electric transmission bodies to connect the first fluid through-holes of the electric transmission bodies and connect the first fluid through-holes to a cooling fluid circuit; and
a second pipe connection member that is insulative and fitted on the second end of each of the electric transmission bodies to connect the second fluid through-holes of the electric transmission bodies and connect the second fluid through-holes to the cooling fluid circuit.

8. The electric connection assembly of claim 7, wherein the first pipe connection member includes:
a pair of first tubular parts respectively fitted on the first ends of the electric transmission bodies;
a first communication part connected between the first tubular parts and having a first communication hole; and
a first pipe joint connected to the first communication part and having a first connection hole, the first connection hole is connected to the first communication hole, the first communication hole is connected to the first fluid through-holes of the electric transmission bodies, the first pipe joint connects to the cooling fluid circuit.

9. The electric connection assembly of claim 8, wherein the second pipe connection member includes:
a pair of second tubular parts respectively fitted on the second ends of the electric transmission bodies;
a second communication part connected between the second tubular parts and having a second communication hole; and
a second pipe joint connected to the second communication part and having a second connection hole, the second connection hole is connected to the second communication hole, the second communication hole is connected to the second fluid through-holes of the electric transmission bodies, the second pipe joint connects to the cooling fluid circuit.

10. The electric connection assembly of claim 9, wherein:
a pair of first sealing rings are fitted on the first ends of the electric transmission bodies, the first sealing rings are respectively positioned on an inner side of the first tubular parts and compressed between the first tubular parts and the electric transmission bodies; and/or
a pair of second sealing rings are fitted on the second ends of the electric transmission bodies, the second sealing rings are respectively positioned on an inner side of the second tubular parts and compressed between the second tubular parts and the electric transmission bodies.

11. The electric connection assembly of claim 9, wherein a first mounting portion is formed on an outer surface of one of the first tubular parts, a first threaded hole is formed in the first mounting portion, and a first positioning hole corresponding to the first threaded hole is formed on the first end of the electric transmission body, a first positioning screw is threaded into the first threaded hole and inserted into the first positioning hole to prevent axial movement and circumferential rotation of the first pipe connection member relative to the electric transmission body.

12. The electric connection assembly of claim 11, wherein a second mounting portion is formed on an outer surface of one of the second tubular parts, a second threaded hole is formed in the second mounting portion, and a second positioning hole corresponding to the second threaded hole is formed on the second end of the electric transmission body, a second positioning screw is threaded into the second threaded hole and inserted into the second positioning hole to prevent axial movement and circumferential rotation of the second pipe connection member relative to the electric transmission body.

13. The electric connection assembly of claim 12, wherein:
a first recess is formed on the first mounting portion to accommodate a head of the first positioning screw, a first sealing ring is provided in the first recess and compressed between the head of the first positioning screw and a bottom surface of the first; and/or
a second recess is formed on the second mounting portion to accommodate a head of the second positioning screw, a second sealing ring is provided in the second recess and compressed between the head of the second positioning screw and the bottom surface of the second recess.

14. The electric connection assembly of claim 9, further comprising a heat shrink tubing that is heat shrunk on an outer side of the electric transmission body of one of the electric connection members to form an outer insulation layer, the first tubular parts and the second tubular parts are wrapped in the heat shrink tubing.

15. The electric connection assembly of claim 7, further comprising a charging seat having a charging seat housing and a charging terminal installed in the charging seat housing, the first connection end of one of the electric connection members is detachably connected to the charging terminal.

16. The electric connection assembly of claim 7, further comprising a charging seat having a charging seat housing, the first connection end of one of the electric connection members is inserted into the charging seat housing and serves as a charging terminal of the charging seat for mating with a mating terminal of a charging gun.

17. The electric connection assembly of claim 15, further comprising a connector including a connector housing, the second connection end of one of the electric connection members is inserted into the connector housing and serves as a connection terminal of the connector for electrically connecting with a busbar of a battery pack.

18. The electric connection assembly of claim 16, further comprising a connector including a connector housing and a connection terminal inserted into the connector housing, the second connection end of one of the electric connection members is detachably connected to the connection terminal of the connector.

19. The electric connection assembly according to claim 17, wherein:
the second pipe connection member is located inside the connector housing and connects with the cooling fluid circuit located inside a battery pack; or
the second pipe connection member is located outside the connector housing and connects with the cooling fluid circuit located outside the battery pack.

20. An electric connection member, comprising:
an electric transmission body having a shape of a hollow tube;
a first connection end connected to a first end of the electric transmission body; and
a second connection end connected to a second end of the electric transmission body, the electric connection member is an integral piece, the first connection end is detachably electrically connected to a connection terminal of a connector or the second connection end is detachably electrically connected to a connection terminal of another connector, an inner cavity of the electric transmission body serves as a flow channel for a cooling fluid, a first fluid through-hole and a second fluid through-hole are formed in a pair of circumferential walls at the first end and the second end of the electric transmission body, the cooling fluid flows into the electric transmission body through one of the first fluid through-hole and the second fluid through-hole and flow out of the electric transmission body through the other of the first fluid through-hole and the second fluid through-hole.
